(19) United States
(12) Patent Application Publication
(10) Pub. No.: US 2026/0198083 A1
(43) Pub. Date: Jul. 9, 2026

(54) SOURCE/DRAIN REGIONS AND CONTACT PLUGS IN STACKING TRANSISTORS AND METHODS OF FORMING THE SAME

(71) Applicant: Taiwan Semiconductor Manufacturing Co., Ltd., Hsinchu (TW)

(72) Inventors: Hsin Yang Hung, New Taipei (TW); Rui-Fu Chen, Hsinchu (TW); Guan-Ren Wang, Hsinchu (TW); Shih-Jung Ho, Hsinchu (TW)

(21) Appl. No.: 19/232,347

(22) Filed: Jun. 9, 2025

Related U.S. Application Data
(60) Provisional application No. 63/743,486, filed on Jan. 9, 2025.

(51) Int. Cl. H10D 84/85; H01L 23/522; H01L 23/528; H10D 30/00; H10D 30/01; H10D 62/10; H10D 62/13; H10D 62/832; H10D 64/23; H10D 64/62; H10D 84/01

(52) U.S. Cl. CPC H10D 84/851; H10D 30/019; H10D 30/502; H10D 62/121; H10D 62/151; H10D 62/832; H10D 64/254; H10D 64/256; H10D 64/62; H10D 84/017; H10D 84/0186; H10W 20/42; H10W 20/435; H10W 20/498

(57) ABSTRACT

A method includes patterning a first opening through a first dielectric layer, a first source/drain region, and a second dielectric layer to expose a second source/drain region; forming a first dielectric liner along sidewalls of the first opening, wherein the second source/drain region is exposed; forming a first metal-semiconductor alloy region in the first opening along the second source/drain region; depositing a first conductive material to fill a remainder of the first opening; patterning a second opening through the first dielectric layer to expose the first source/drain region; forming a second dielectric liner along sidewalls of the second opening, wherein the first source/drain region is exposed; forming a second metal-semiconductor alloy region in the second opening along the first source/drain region; and depositing a second conductive material to fill a remainder of the second opening.

### PRIORITY CLAIM AND CROSS-REFERENCE

This application claims the benefit of the following provisionally filed U.S. Patent application: Application No. 63/743,486, filed on Jan. 9, 2025, and entitled “MDLI FIRST METHOD,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3, 4A, 4B, 5A, 5B, 6A, 6B, 7A, 7B, 8A, 8B, 9A, 9B, 10A, 10B, 11A, 11B, 12A, 12B, 13A, 13B, 14A, and 14B are views of intermediate stages in the manufacturing of stacking transistors, in accordance with some embodiments.

FIGS. 15A and 15B are views of an intermediate stage in the manufacturing of stacking transistors, in accordance with some embodiments.

FIGS. 16A and 16B are views of an intermediate stage in the manufacturing of stacking transistors, in accordance with some embodiments.

FIGS. 17A and 17B are views of an intermediate stage in the manufacturing of stacking transistors, in accordance with some embodiments.

FIG. 18 is a view of intermediate stages in the manufacturing of stacking transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the sake of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure and the method of forming the same are provided. Stacking transistor structures, such as CFETs, and the method of forming the same are provided. The stacking transistor structure includes two transistors that are vertically stacked and that are of opposite types (e.g., an n-type transistor and a p-type transistor that are vertically stacked). As such, source/drain regions of vertically stacked transistors may also be vertically stacked. In addition, source/drain region contacts may be formed to the upper source/drain regions and/or the lower source/drain regions. For example, some source/drain contacts may be formed to couple lower source/drain regions with upper source/drain regions. These contacts may be dual source/drain contacts which include a lower contact and an upper contact which are coupled to one another. Embodiments discussed herein allow for improvements in regrowth of epitaxial material on the source/drain regions, greater specificity and tuning of dopants therein, seamless filling to form the source/drain contacts, and greater control and versatility in the formation and shape of the lower and upper source/drain contacts. In accordance with various embodiments, the source/drain regions and the source/drain contacts are formed with better tuning and improved yield, which results in greater performance and reliability of the stacking transistors.

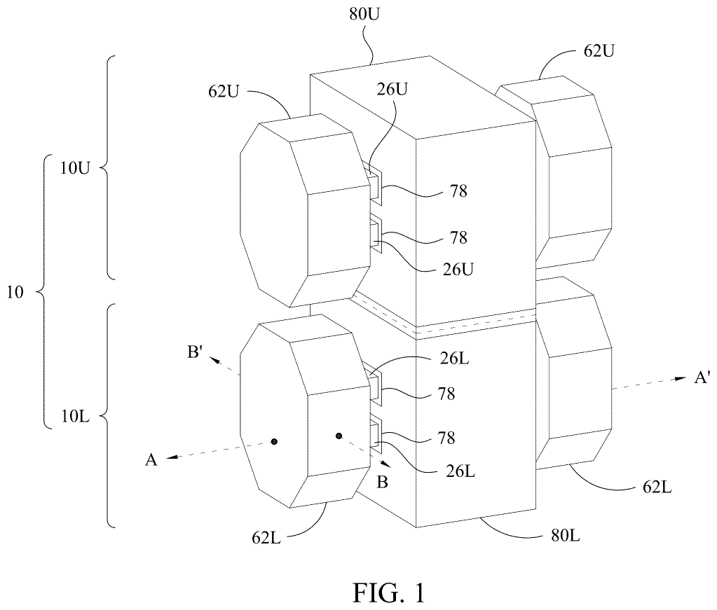

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Cross-section B-B′ is a vertical cross-section that is perpendicular to cross-section A-A′ and extends through the source/drain regions 62 of the stacking transistor. Subsequent figures may refer to these reference cross-sections for clarity.

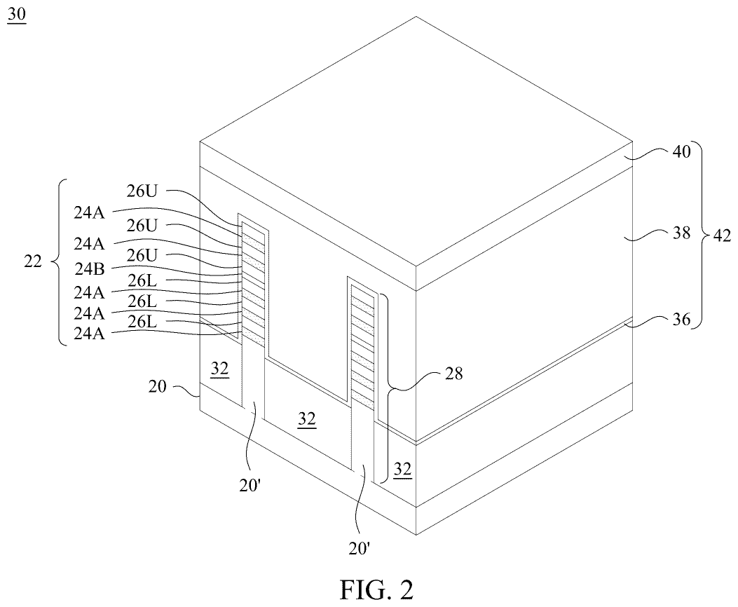

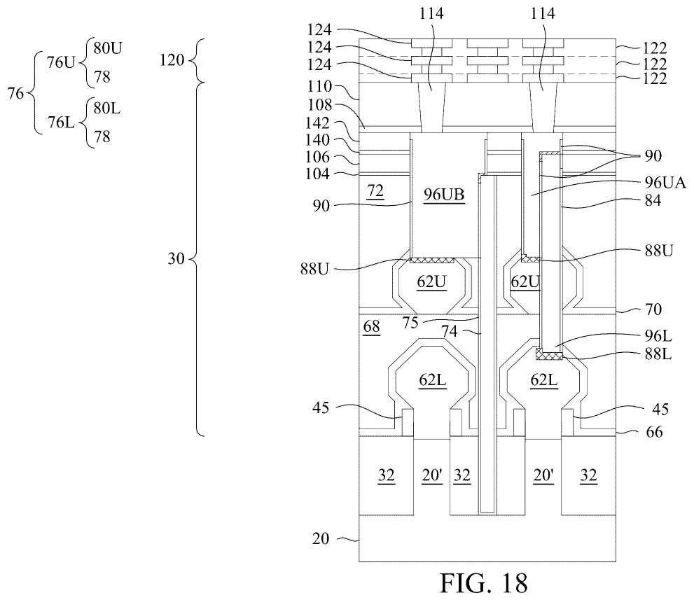

FIGS. 2 through 18 illustrate the cross-sectional views of intermediate stages in the formation of stacking transistors (as schematically represented in FIG. 1) in accordance with some embodiments. In subsequent discussion, unless specified otherwise, the figures having digits followed by letter “A” illustrate the vertical cross-sectional views along a similar cross-section as vertical reference cross-section A-A′ in FIG. 1. The figures having digits followed by letter “B” illustrate the vertical cross-sectional views along a similar cross-section as the vertical reference cross-section B-B′ in FIG. 1. In addition, FIG. 18 illustrates the vertical cross-section B-B′.

In FIG. 2, a wafer, which includes a device layer 30 being formed over a substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked components of the multi-layer stack 22 are referred to as nanostructures hereinafter. Specifically, the multi-layer stack 22 includes dummy nanostructures 24A, one or more dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32 such as shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) may be recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

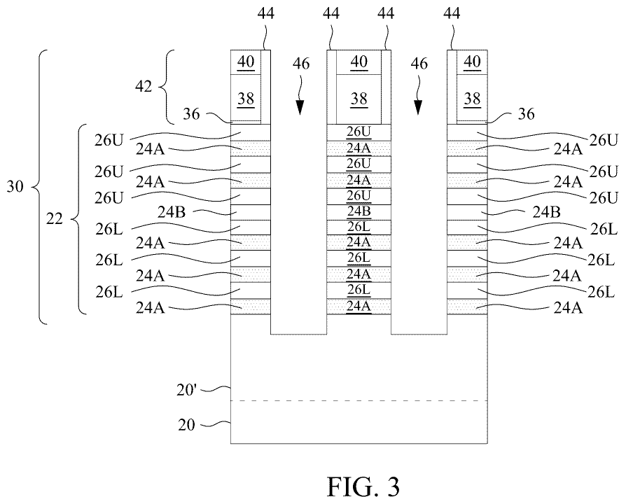

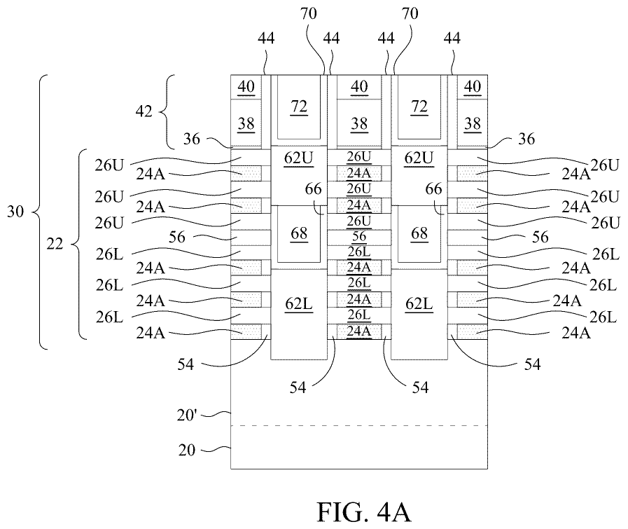

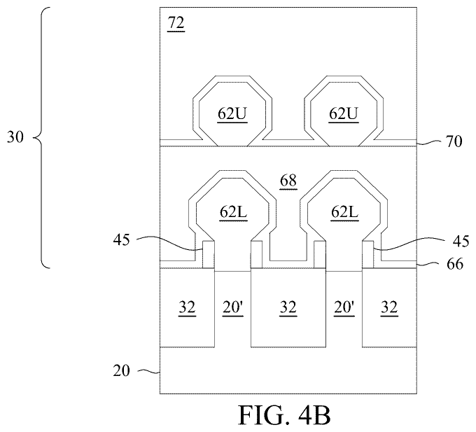

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 (see FIG. 4B) may also be formed as part of forming the gate spacers 44.

Subsequently, source/drain recesses 46 are formed in semiconductor strips 28. The source/drain recesses 46 are formed through etching, and may extend through the multi-layer stacks 22 and into the semiconductor strips 20′. Bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

FIGS. 4A and 4B illustrate various subsequent processing steps. FIG. 4A and subsequent figures having digits followed by letter “A” illustrate the A-A′ cross-section of the structure, and FIG. 4B and subsequent figures having digits followed by letter “B” illustrate the B-B′ cross-section of the structure. In particular, inner spacers 54 and dielectric isolation layers 56 are formed. Forming the inner spacers 54 and the dielectric isolation layers 56 may include an etching process that laterally etches the dummy nanostructures 24A and removes the dummy nanostructures 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

The inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As further illustrated by FIGS. 4A and 4B, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy processes of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed. The resulting epitaxial source/drain regions 62 may include a plurality of semiconductor layers. For example, a first semiconductor layer includes a first element (e.g., silicon, germanium, boron, phosphorous, etc.) and a second semiconductor layer also includes the first element, wherein a concentration of the first element in the semiconductor layers changes in a direction towards the substrate. In addition, in a cross-section such as illustrated in FIG. 4B, a thickness of the epitaxial source/drain region 62 may be different from a width of the epitaxial source/drain region 62.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper epitaxial source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for the second CESL 70 and the second ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 72. In the illustrated embodiment, the masks 40 remain after the removal process. In other embodiments, the masks 40 are removed such that the top surfaces of the dummy gates 38 are exposed through the second ILD 72.

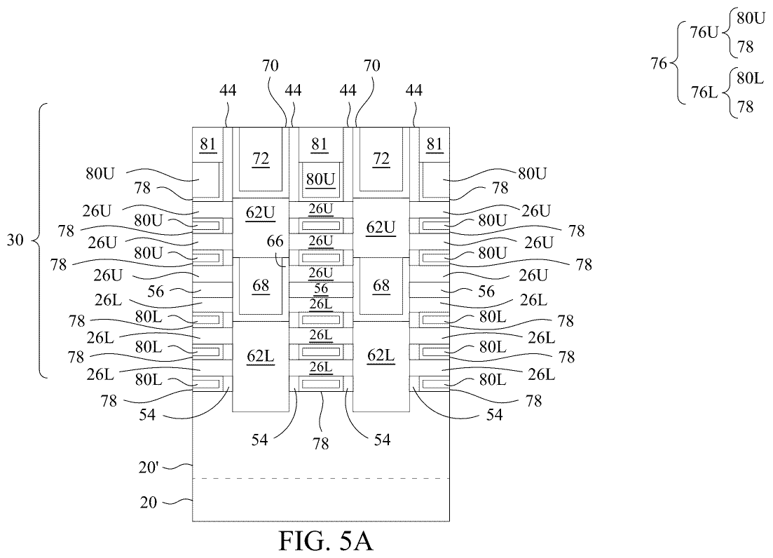

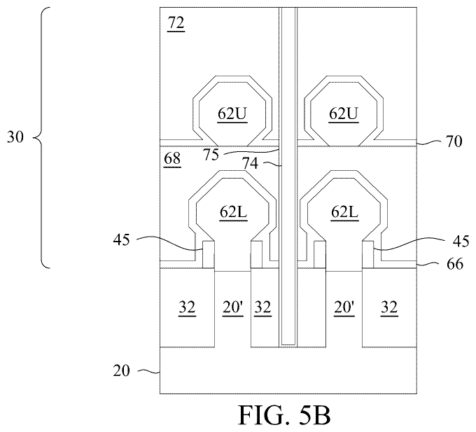

In FIGS. 5A and 5B, a replacement gate process is performed to replace the dummy gate stacks 42 and the dummy nanostructures 24A with gate stacks 76. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the material of the dummy nanostructures 24A is etched at a faster rate than the materials of the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 9.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, tungsten nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 76 (including upper gate structures 76U and lower gate structures 76L). Each gate structure 76 extends along three sides (e.g., a top surface, a sidewall, and a bottom surface) of a channel region of a semiconductor nanostructure 26 (see FIG. 1). The lower gate structures 76L may also extend along sidewalls and/or a top surface of a semiconductor fin 20′.

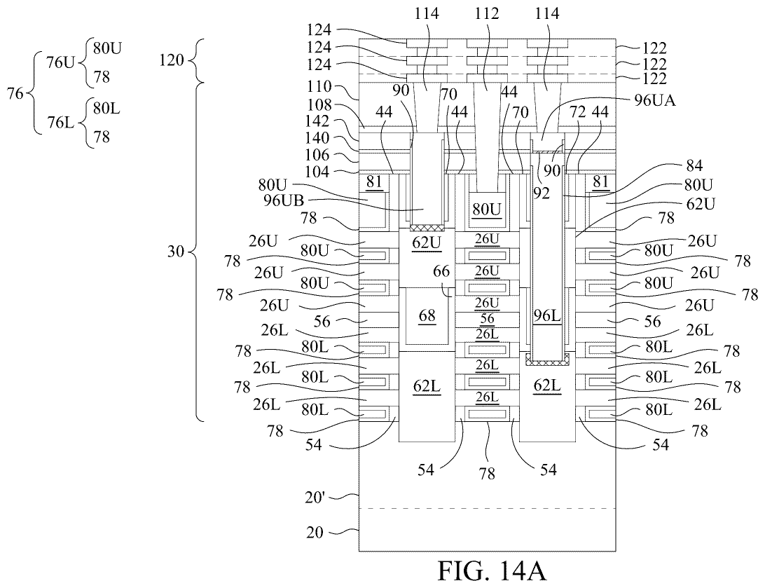

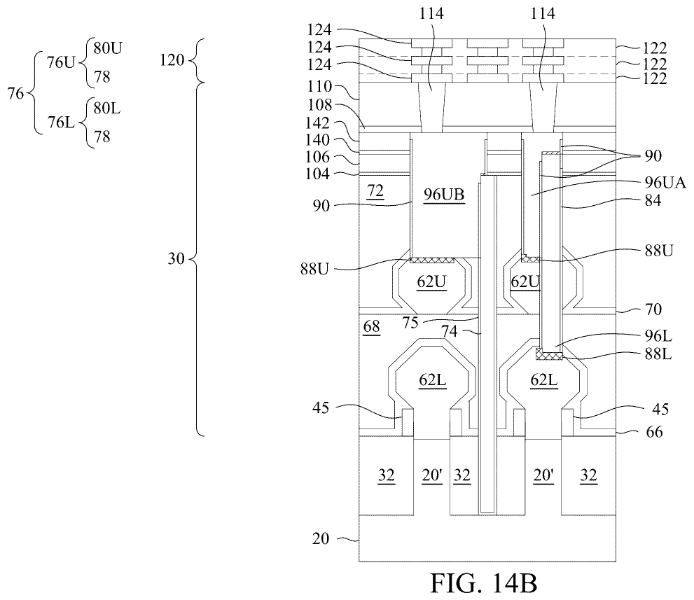

In some embodiments (see, e.g., FIGS. 14A-17A), gate masks 81 may be formed over the gate stacks 42. The formation process may include recessing gate stacks 76, filling the resulting recesses with a dielectric material such as silicon nitride, silicon carbonitride, silicon oxynitride, silicon oxycarbonitride, the like, or a combination thereof, and performing a planarization process to remove the excess portions of the dielectric material over the second ILD 72. In some embodiments, the gate masks 81 are formed in a later processing step or may be omitted.

As further illustrated by FIG. 5B, contact vias 74 having contact spacers 75 disposed on sidewalls thereof are formed to extend at least partially through the device layer 30. As an example to form the contact vias 74, openings may be formed through the second ILD 72, the second CESL 70, the first ILD 68, the first CESL 66, the STI regions 32, and any other intervening layers by a combination of photolithography and etching processes. The contact spacers 75 may be deposited along sidewalls of the openings using a suitable dielectric material. The contact vias 74 are then formed in the openings and may include a plurality of layers (not separately illustrated), such as a liner (e.g., a diffusion barrier layer, an adhesion layer, and/or the like) and a conductive material. The liner may include titanium, titanium nitride, tantalum, tantalum nitride, the like, or combinations thereof. The conductive material may be cobalt, tungsten, copper, a copper alloy, silver, gold, aluminum, nickel, or the like. A planarization process, such as a CMP, may be performed to remove excess material from the top surface of the second ILD 72. The remaining liner and conductive material form the contact vias 74.

In some embodiments, the contact spacers 75 may comprise silicon nitride, silicon oxide, silicon oxynitride, silicon oxycarbonitride, combinations thereof, or the like and may be formed by conformally depositing an insulating material layer by CVD, ALD, or the like. Then, lateral portions of the insulating material layer may be etched away by an anisotropic etching process, such as a plasma-based dry etch, thereby forming the contact spacers 75. Conductive material is then formed in the opening and may include cobalt, tungsten, copper, a copper alloy, silver, gold, aluminum, nickel, or the like. A planarization process, such as a CMP, may be performed to remove excess material from the top surface of the second ILD 72.

As illustrated, the contact vias 74 and the contact spacers 75 may be formed through the first CESL 66, the first ILD 68, the second CESL 70, the second ILD 72, and the STI regions 32. As shown in connection with subsequent figures, the contact vias 74 may provide electrical connection to a back-side interconnect structure 134 and/or a front-side interconnect structure 120 (e.g., which may be through subsequently formed upper source/drain contacts). In this manner, interconnection between the front-side interconnect structure 120 and the back-side interconnect structure 134 may be achieved.

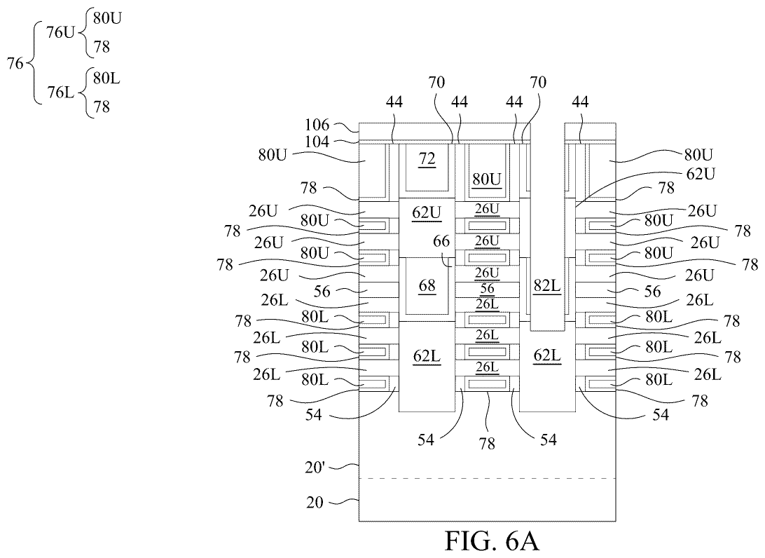

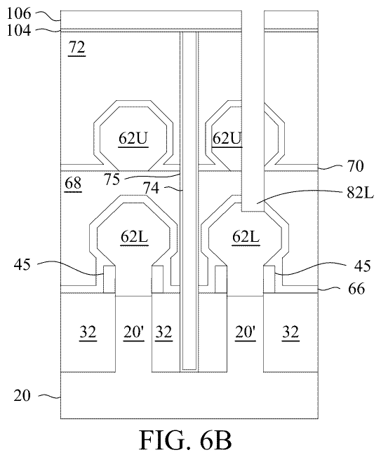

FIGS. 6A through 14B illustrate formation of source/drain contacts 96 (e.g., contact plugs) and front-side interconnect structure 120 to electrically couple to the upper epitaxial source/drain regions 62U and the lower epitaxial source/drain regions 62L, in accordance with some embodiments. FIGS. 6A, 7A, 8A, 9A, 10A, 11A, 12A, 13A, and 14A illustrate the A-A′ cross-section of the structure, and FIGS. 6B, 7B, 8B, 9B, 10B, 11B, 12B, 13B, and 14B illustrate the B-B′ cross-section of the structure. As described in greater detail below, lower source/drain contact openings 82L are formed to the lower epitaxial source/drain regions 62L, lower source/drain contacts 96L are formed in the lower source/drain contact openings 82L, upper source/drain contact openings 82U are formed to the upper epitaxial source/drain regions 62U, and upper source/drain contacts 96U are formed in the upper source/drain contact openings 82U.

In FIGS. 6A and 6B, a third ILD 106 may be formed over the second ILD 72 and the upper gate structures 76U, and lower source/drain contact openings 82L are formed through the third ILD 106, the second ILD 72, the upper epitaxial source/drain regions 62U, and the first ILD 68 to the lower epitaxial source/drain regions 62L. In some embodiments, a third CESL 104 may be formed before forming the third ILD 106. The third CESL 104 may be formed of a dielectric material having a high etching selectivity from the etching of the third ILD 106, such as silicon nitride, silicon oxide, silicon oxynitride, aluminum oxide, aluminum nitride, silicon oxycarbide, or the like, which may be formed by any suitable deposition process, such as CVD, ALD, or the like. The third ILD 106 may be formed using flowable CVD, ALD, or the like, and the material may include PSG, BSG, BPSG, USG, or the like, which may be deposited by any suitable method, such as CVD, PECVD, or the like.

For example, the lower source/drain contact openings 82L are formed to expose (and optionally extend into) the lower epitaxial source/drain regions 62L. Specifically, the lower source/drain contact openings 82L may extend through the third ILD 106, the third CESL 104, the second ILD 72, the second CESL 70, the overlying upper epitaxial source/drain regions 62U, the first ILD 68, and/or the first CESL 66 to expose and extend partially into the lower epitaxial source/drain regions 62L.

In some embodiments, the lower source/drain contact openings 82L may be formed by a combination of sequential photolithography and etching processes. In accordance with some embodiments, the lower source/drain contact openings 82L (and the lower source/drain contacts 96L) are formed prior to forming the upper source/drain contact openings 82U (and the upper source/drain contacts 96U).

In accordance with various embodiments, the lower source/drain contact openings 82L may have high aspect ratios. For example, the aspect ratios of the lower source/drain contact openings 82L may be up to about 8 to about 15. In addition, widths (e.g., diameters) of the lower source/drain contact openings 82L may range from about 4 nm to about 15 nm with depths ranging from about 32 nm to about 225 nm.

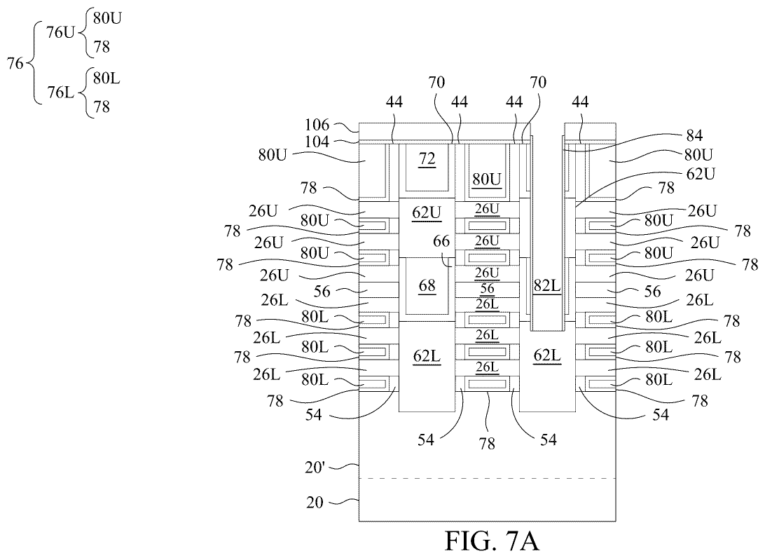

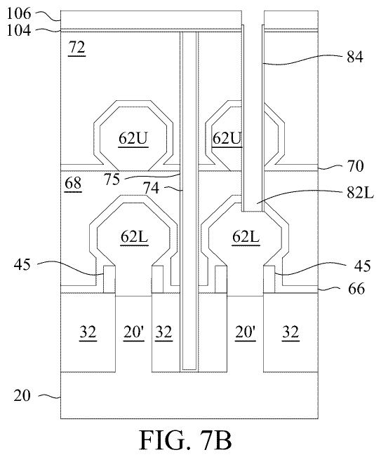

In FIGS. 7A and 7B, a first dielectric liner 84 is formed along sidewalls of the lower source/drain contact openings 82L. The first dielectric liner 84 may be formed of similar materials and by similar processes as described above in connection with the contact spacers 75. For example, the first dielectric liner 84 may comprise a silicon nitride, including silicon oxynitride, silicon oxycarbonitride, or the like, and may be formed by conformally depositing an insulating material layer by CVD, ALD, or the like. Then, lateral portions of the insulating material layer may be etched away by an anisotropic etching process, such as a plasma-based dry etch, thereby forming the first dielectric liner 84.

As illustrated, in some embodiments, surfaces of the lower epitaxial source/drain regions 62L may be exposed after the etching process. In addition, upper portions of the first dielectric liner 84 may be recessed from topmost surfaces of the structure (e.g., the third ILD 106). In other embodiments (not specifically illustrated), some portions of the first dielectric liner 84 may remain such that the upper portions may be substantially level with topmost surfaces of the structure (e.g., the third ILD 106).

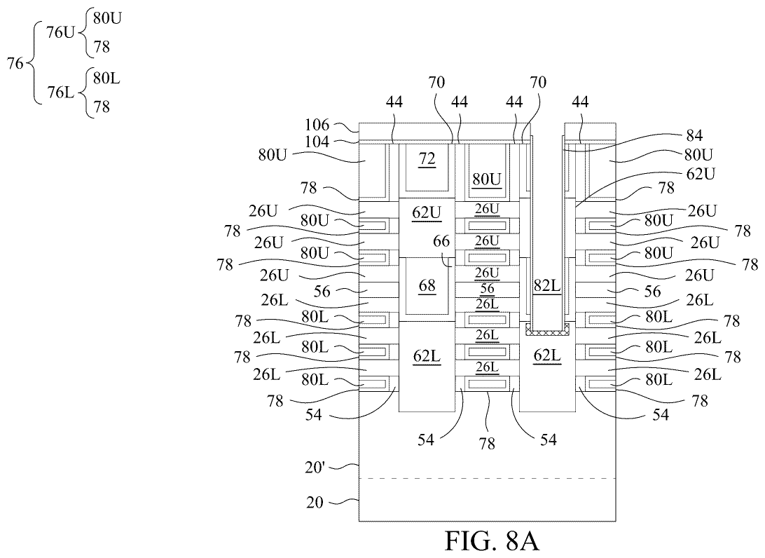

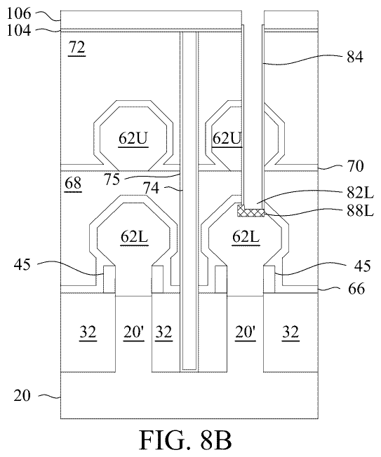

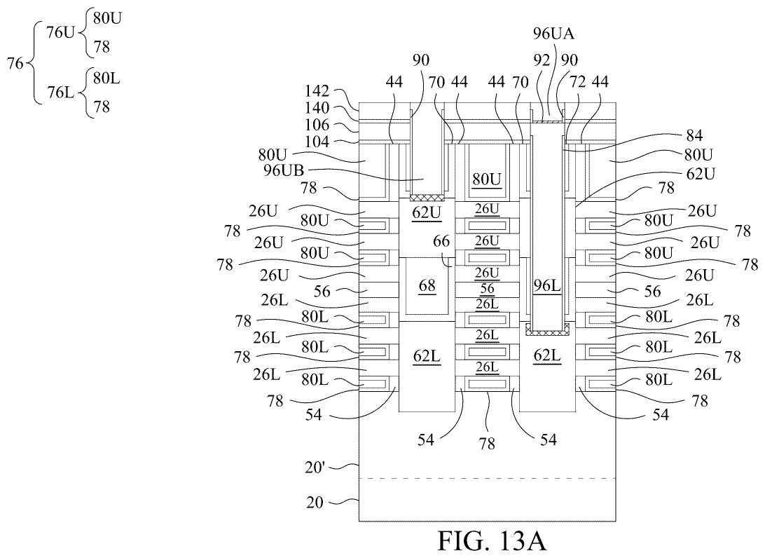

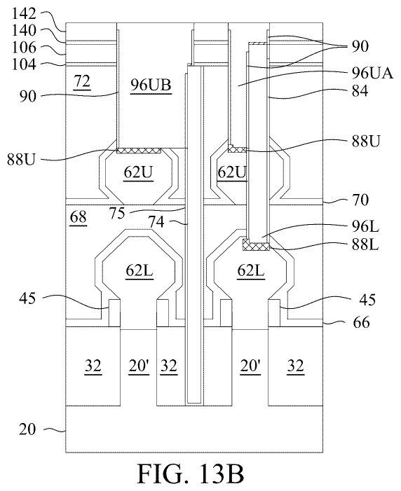

In FIGS. 8A and 8B, lower metal-semiconductor alloy regions 88L are formed along the exposed surfaces of the lower epitaxial source/drain regions 62L. The lower metal-semiconductor alloy regions 88L will be at interfaces between the lower epitaxial source/drain regions 62L and the subsequently formed lower source/drain contacts 96L (see FIGS. 13A and 13B). The lower metal-semiconductor alloy regions 88L can be silicide regions formed of a metal silicide (e.g., nickel silicide (NiSi), titanium silicide (TiSi), tungsten silicide (WSi), molybdenum silicide (MoSi), ruthenium silicide (RuSi), zirconium silicide (ZrSi), antimony silicide (SbSi), cobalt silicide (CoSi), palladium silicide (PdSi), etc.), germanide regions formed of a metal germanide (e.g. nickel germanide (NiGe), titanium germanide (TiGe), tungsten germanide (WGe), molybdenum germanide (MoGe), ruthenium germanide (RuGe), zirconium germanide (ZrGe), antimony germanide (SbGe), cobalt germanide (CoGe), palladium germanide (PdGe), etc.), silicon-germanide regions formed of both a metal silicide and a metal germanide, or the like. Note that, for the sake of simplicity, sometimes the metal-semiconductor alloy regions 88 may be broadly referred to as silicide regions or metal silicide regions to include the above-listed silicides, germanides, and/or silicon-germanides.

The lower metal-semiconductor alloy regions 88L can be formed by depositing a metal (e.g., as identified above) in the lower source/drain contact openings 82L and then performing a thermal anneal process. The metal can be any metal capable of reacting with the semiconductor materials (e.g., silicon, silicon-germanium, germanium, etc.) of the lower epitaxial source/drain regions 62L to form a low-resistance metal-semiconductor alloy, such as nickel, titanium, tungsten, molybdenum, ruthenium, zirconium, antimony, cobalt, palladium, tantalum, platinum, other noble metals, other refractory metals, rare earth metals, or their alloys.

In addition, the metal can be deposited by a deposition process such as ALD, CVD, PVD, or the like. After the thermal anneal process, a cleaning process, such as a wet clean, may be performed to remove any residual metal from the lower source/drain openings 82L for the lower source/drain contacts 96L, such as from surfaces of the lower metal-semiconductor alloy regions 88L. In some embodiments, the lower metal-semiconductor alloy regions 88L (e.g., comprising silicon germanium epitaxial material) are formed of MoSiGe, RuSiGe, NiSiGe, PtSiGe, PdSiGe, or NbSiGe, wherein the metal is deposited by CVD or PVD followed by the thermal anneal process with temperatures ranging from 400° C. to 1000° C. As such, the lower metal-semiconductor alloy region 88L can be near the silicon valence band.

Optionally, the lower epitaxial source/drain regions 62L may be implanted with a dopant and activated with a thermal anneal process. For example, in embodiments in which the lower source/drain region 62L comprises silicon germanium epitaxial material, the implantation process may include boron dopants followed by an anneal at temperatures ranging from 800° C. to 1200° C. Alternatively, in embodiments in which the lower source/drain region 62L comprises silicon epitaxial material, the implantation process may include phosphorous and/or arsenic dopants followed by an anneal at temperatures ranging from 800° C. to 1200° C. In either case, the implantation increases the dopant concentration to improve performance of the lower epitaxial source/drain regions 62L and reduce resistance with the lower metal-semiconductor alloy regions 88L.

In accordance with some embodiments, the implantation process may be performed before formation of the lower metal-semiconductor alloy regions 88L. In other embodiments, the implantation process may occur in parallel with (e.g., intertwined with) or after formation of the lower metal-semiconductor alloy regions 88L. As noted above, the implantation process for the lower epitaxial source/drain regions 62L may be specific to the conductivity type of the lower transistor of the stacking transistors due to the upper epitaxial source/drain region 62U being covered and protected by the first dielectric liner 84.

Presence of the first dielectric liner 84 along the sidewalls of the lower source/drain contact openings 82L provides advantages. For example, the first dielectric liner 84 serves as a protective barrier to the upper epitaxial source/drain regions 62U during formation of the lower metal-semiconductor alloy regions 88L. As a result, the materials and process conditions for forming the lower metal-semiconductor alloy regions 88L may be selected to improve the electrical connection between the lower epitaxial source/drain regions 62L and subsequently formed lower source/drain contacts 96L. In addition, the implantation process (if performed) may utilize dopants and process conditions which may differ from those subsequently used in an implantation process used for the upper epitaxial source/drain regions 62U (if performed).

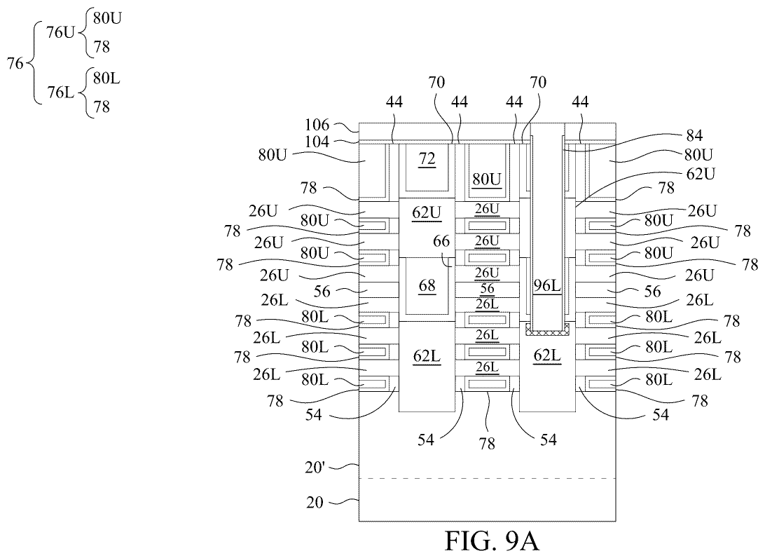

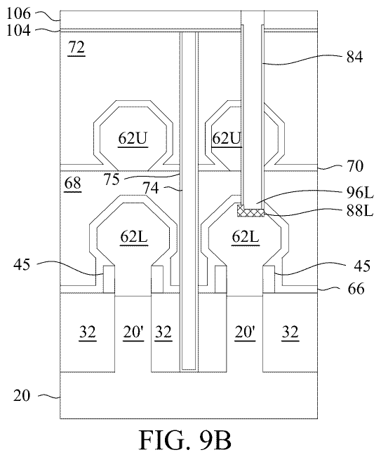

In FIGS. 9A and 9B, lower source/drain contacts 96L are formed in the lower source/drain contact openings 82L to electrically couple to the lower epitaxial source/drain regions 62L. For example, a first conductive material is deposited to fill remainders of the lower source/drain contact openings 82L. In some embodiments, the first conductive material may be a metal such as ruthenium, tungsten, molybdenum, cobalt, copper, a copper alloy, silver, gold, aluminum, nickel, combinations thereof, or the like and may be formed by a plating process, PVD, CVD, ALD, or the like. A removal process may be performed to remove excess first conductive material from the top surfaces of the gate spacers 44 and the third ILD 106. The remaining first conductive material form the lower source/drain contacts 96L in the lower source/drain contact openings 82L. In some embodiments, a planarization process such as a CMP, an etch-back process, combinations thereof, or the like is utilized. After the planarization process, the top surfaces of the gate spacers 44, the third ILD 106, and the lower source/drain contacts 96L are substantially coplanar (within process variations).

In accordance with various embodiments, the lower metal-semiconductor alloy region 88L may serve as a seed layer in the deposition of the first conductive material to form the lower source/drain contacts 96L. The first conductive material may fill the lower source/drain contact openings 82L from the bottom upward, such as from the lower metal-semiconductor alloy regions 88L and upward toward the upper portions of the lower source/drain contact openings 82L. In particular, the first conductive material deposits over the lower metal-semiconductor alloy regions 88L and over itself at greater rates than along the first dielectric liner 84 along the sidewalls. As a result, the first conductive material can fill the lower source/drain contact openings 82L to form the lower source/drain contacts 96L to be substantially seamless or without voids caused by pinching. The resulting lower source/drain contacts 96L can be formed at a greater yield along with a higher performance and reliability.

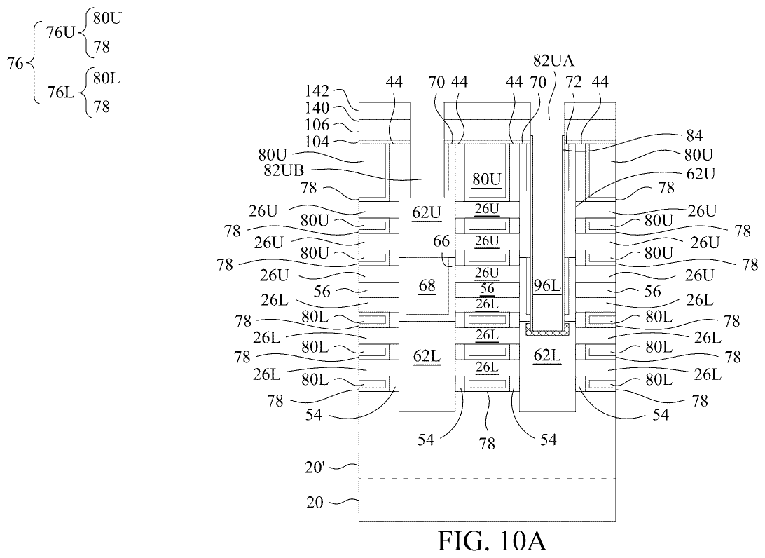

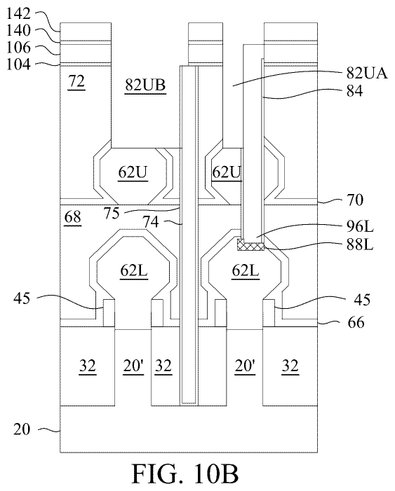

In FIGS. 10A and 10B, a fourth ILD 142 may be formed over the third ILD 106, and first upper source/drain contact openings 82UA and second upper source/drain contact openings 82UB are formed through the fourth ILD 142, the third ILD 106, and the second ILD 72 to the upper epitaxial source/drain regions 62U. In some embodiments, a fourth CESL 140 may be formed before forming the fourth ILD 142. The fourth CESL 140 may be formed of a dielectric material having a high etching selectivity from the etching of the fourth ILD 142, such as silicon nitride, silicon oxide, silicon oxynitride, aluminum oxide, aluminum nitride, silicon oxycarbide, or the like, which may be formed by any suitable deposition process, such as CVD, ALD, or the like. The fourth ILD 142 may be formed using flowable CVD, ALD, or the like, and the material may include PSG, BSG, BPSG, USG, or the like, which may be deposited by any suitable method, such as CVD, PECVD, or the like.

For example, the upper source/drain contact openings 82U are formed to expose (and optionally extend into) the upper epitaxial source/drain regions 62U. Specifically, the upper source/drain contact openings 82U may extend through the fourth ILD 142, the third ILD 106, and the second CESL 70 to expose and extend partially into the upper epitaxial source/drain regions 62U. The first upper source/drain contact openings 82UA will subsequently house first upper source/drain contacts 96UA which are connected to corresponding ones of the lower source/drain contacts 96L. The second upper source/drain contact openings 82UB will subsequently house second upper source/drain contacts 96UB which may or may not be connected to corresponding contact vias 74. The upper source/drain contact openings 82U may be formed similarly as described above in connection with the lower source/drain contact openings 82L, such as using one or more photolithography and/or etching processes.

As illustrated, the first upper source/drain contact openings 82UA may expose sidewalls of the lower source/drain contacts 96L and/or portions of their respective first dielectric liners 84. As discussed in greater detail below, corresponding pairs of the first upper source/drain contacts 96UA and the lower source/drain contacts 96L may be referred to collectively as dual source/drain contacts 96D. As a result, the corresponding upper and lower epitaxial source/drain regions 62U, 62L may be electrically coupled by the subsequently formed dual source/drain contacts 96D (see FIGS. 13A and 13B).

As further illustrated, some of the second upper source/drain contact openings 82UB may expose sidewalls of the contact vias 74. As a result, the corresponding upper epitaxial source/drain regions 62U may be electrically coupled to other integrated circuit features by the subsequently formed upper source/drain contacts 96UB and the respective contact vias 74. Although not specifically illustrated, others of the second upper source/drain contact openings 82UB may expose the corresponding upper epitaxial source/drain regions 62U without exposing any of the contact vias 74 or the lower source/drain contacts 96L. In addition, the first upper source/drain contact openings 82UA may expose a portion or an entirety of the upper surfaces of the corresponding lower source/drain contacts 96L. Similarly, the second upper source/drain contact openings 82UB may expose a portion or an entirety of the upper surfaces of the corresponding contact vias 74.

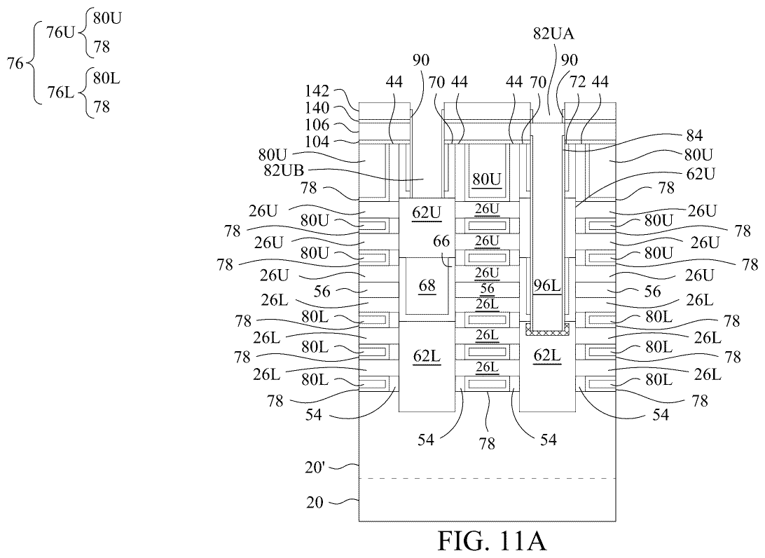

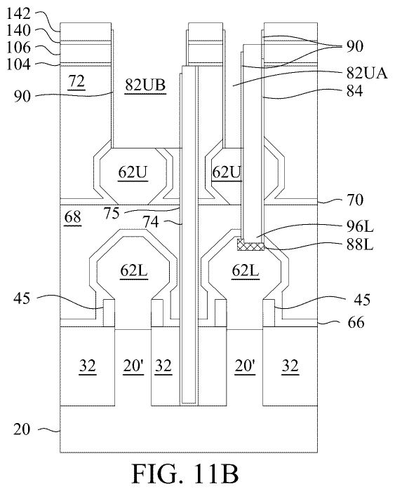

In FIGS. 11A and 11B, a second dielectric liner 90 is formed along sidewalls of the upper source/drain contact openings 82U. The second dielectric liner 90 may be formed of similar materials and by similar processes as described above in connection with the first dielectric liner 84. The second dielectric liner 90 may be a same or different material as the first dielectric liner 84. For example, the second dielectric liner 90 may comprise a silicon nitride, including silicon oxynitride, silicon oxycarbonitride, or the like, and may be formed by conformally depositing an insulating material layer by CVD, ALD, or the like. Then, lateral portions of the insulating material layer may be etched away by an anisotropic etching process, such as a plasma-based dry etch, thereby forming the second dielectric liner 90.

As illustrated, in some embodiments, surfaces of the upper epitaxial source/drain regions 62U may be exposed after the etching process. In addition, upper portions of the second dielectric liner 90 may be recessed from topmost surfaces of the structure (e.g., the fourth ILD 142). In other embodiments (not specifically illustrated), some portions of the second dielectric liner 90 may remain such that the upper portions may be substantially level with topmost surfaces of the structure (e.g., the fourth ILD 142). Either of these phenomena may also occur with respect to topmost surfaces of the lower source/drain contacts 96L and the contact vias 74.

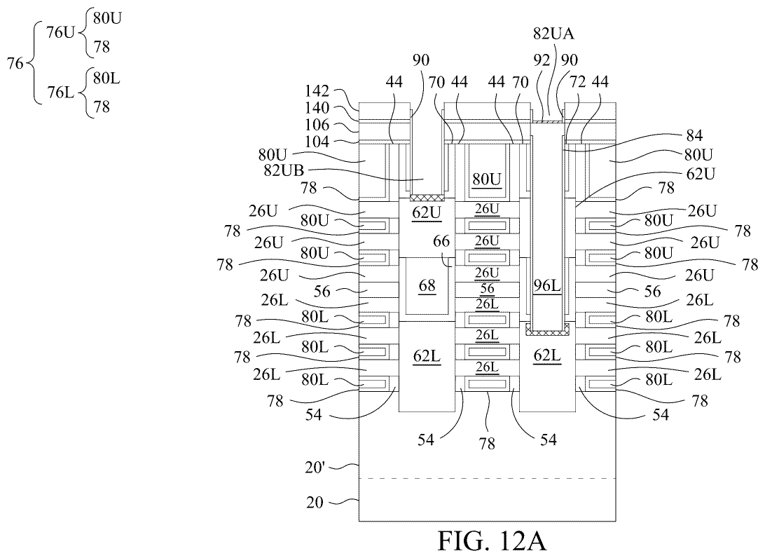

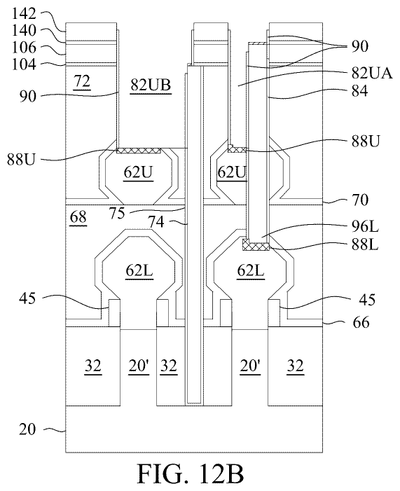

In FIGS. 12A and 12B, upper metal-semiconductor alloy regions 88U are formed along the exposed surfaces of the upper epitaxial source/drain regions 62U. The upper metal-semiconductor alloy regions 88U will be at interfaces between the upper epitaxial source/drain regions 62U and the subsequently formed upper source/drain contacts 96U (see FIGS. 13A and 13B). The upper metal-semiconductor alloy regions 88U may be formed of similar materials and by similar processes as described above in connection with the lower metal-semiconductor alloy regions 88L. For example, the upper metal-semiconductor alloy regions 88U may be silicide regions formed of a metal silicide (e.g., NiSi, TiSi, WSi, MoSi, RuSi, ZrSi, SbSi, CoSi, PdSi, etc.), germanide regions formed of a metal germanide (e.g. NiGe, TiGe, WGe, MoGe, RuGe, ZrGe, SbGe, CoGe, PdGe, etc.), silicon-germanide regions formed of both a metal silicide and a metal germanide, or the like. As noted above, for the sake of simplicity, sometimes the metal-semiconductor alloy regions 88 may be broadly referred to as silicide regions or metal silicide regions to include the above-listed silicides,

The upper metal-semiconductor alloy regions 88U can be formed by depositing a metal (e.g., as identified above) in the upper source/drain contact openings 82U and then performing a thermal anneal process. The metal can be any metal capable of reacting with the semiconductor materials (e.g., silicon, silicon-germanium, germanium, etc.) of the upper epitaxial source/drain regions 62U to form a low-resistance metal-semiconductor alloy, such as nickel, titanium, tungsten, molybdenum, ruthenium, zirconium, antimony, cobalt, palladium, tantalum, platinum, other noble metals, other refractory metals, rare earth metals, or their alloys.

In addition, the metal can be deposited by a deposition process such as ALD, CVD, PVD, or the like. After the thermal anneal process, a cleaning process, such as a wet clean, may be performed to remove any residual metal from the upper source/drain openings 82U (before forming the upper source/drain contacts 96U), such as from surfaces of the upper metal-semiconductor alloy regions 88U. In some embodiments, the upper metal-semiconductor alloy regions 88U (e.g., comprising silicon epitaxial material) are formed of TiSi, MoSi, RuSi, NiSi, PtSi, PdSi, NbSi, or combinations thereof, wherein the metal is deposited by CVD or PVD followed by the thermal anneal process with temperatures ranging from 400° C. to 1000° C.

Optionally, the upper epitaxial source/drain regions 62U may be implanted with a dopant and activated with a thermal anneal process. For example, in embodiments in which the upper epitaxial source/drain region 62U comprises silicon epitaxial material, the implantation process may include phosphorous and/or arsenic dopants followed by an anneal at temperatures ranging from 800° C. to 1200° C. Alternatively, in embodiments in which the upper source/drain region 62U comprises silicon germanium epitaxial material, the implantation process may include boron dopants followed by an anneal at temperatures ranging from 800° C. to 1200° C. In either case, the implantation increases the dopant concentration to improve performance of the upper epitaxial source/drain regions 62U and reduce resistance with the upper metal-semiconductor alloy regions 88U.

In accordance with some embodiments, the implantation process may be performed before formation of the upper metal-semiconductor alloy regions 88U. In other embodiments, the implantation process may occur in parallel with (e.g., intertwined with) or after formation of the upper metal-semiconductor alloy regions 88U. As noted above, the implantation process for the upper epitaxial source/drain regions 62U may be specific to the conductivity type of the upper transistor of the stacking transistors due to the lower epitaxial source/drain region 62L being covered and protected by the lower source/drain contact 96L.

In some embodiments, the upper metal-semiconductor alloy regions 88U may include titanium (e.g., comprising TiSi). For example, deposition of the one or more metal (e.g., including titanium) over the upper epitaxial source/drain regions 62U may also result in those metal(s) (e.g., titanium) being deposited over other exposed surfaces, such as the metal surfaces of the lower source/drain contacts 96L and/or the contact vias 74. After forming the upper metal-semiconductor alloy regions 88U, a metal nitride layer 92 (e.g., titanium nitride). Subsequent cleaning steps to remove non-silicided metals may remove none or some of the metal nitride layer 92.

It should be appreciated that interfaces between the metal nitride layer 92 and adjacent conductive materials may have non-negligible resistance (e.g., a relatively high metal-to-metal resistance) at various operating conditions (e.g., including a set of standard conditions). The adjacent conductive material may include the first conductive material of the lower source/drain contacts 96L, the conductive material of the contact vias 74, or a second conductive material of subsequently formed upper source/drain contacts 96U. However, in some embodiments, the above-described implantation process (if performed after formation of the upper metal-semiconductor alloy regions 88U) may result in the dopants (e.g., phosphorous and/or arsenic) implanting, damaging, and/or disrupting the metal nitride layer 92. The interfaces between the damaged metal nitride layer 92 and the adjacent conductive materials may decrease (e.g., to a relatively low metal-to-metal resistance) at the same conditions (e.g., operating conditions, such as a set of standard conditions). Optionally, a treatment process may be performed to remove the metal nitride layer 92. For example, a treatment using chlorine gas may assist pull back or removal of the metal nitride layer 92. In addition or alternatively, subsequently deposited conductive material may comprise a same material, such as a same metal nitride in order to reduce resistance caused by the metal nitride layer 92.

Having already performed the previously described process steps over the lower epitaxial source/drain regions 62L through the lower source/drain contact openings 82L and forming the lower source/drain contacts 96L provides advantages. For example, the lower source/drain contacts 96L analogously protect the lower epitaxial source/drain regions 62L (and the lower metal-semiconductor alloy regions 88L) during formation of the upper metal-semiconductor alloy regions 88U. As a result, the materials and process conditions for forming the upper metal-semiconductor alloy regions 88U may be selected to improve the electrical connection between the upper epitaxial source/drain regions 62U and subsequently formed upper source/drain contacts 96U. In addition, the implantation process (if performed) may utilize dopants and process conditions which may differ from those previously used in the implantation process used for the lower epitaxial source/drain regions 62L (if performed).

In FIGS. 13A and 13B, upper source/drain contacts 96U are formed in the upper source/drain contact openings 82U to electrically couple to the upper epitaxial source/drain regions 62U. For example, a second conductive material is deposited to fill remainders of the upper source/drain contact openings 82U. In some embodiments, the second conductive material may be a metal such as ruthenium, tungsten, molybdenum, cobalt, copper, a copper alloy, silver, gold, aluminum, nickel, combinations thereof, or the like and may be formed by a plating process, PVD, CVD, ALD, or the like. A removal process may be performed to remove excess second conductive material from the top surfaces of the fourth ILD 142. The remaining second conductive material form the upper source/drain contacts 96U in the upper source/drain contact openings 82U. In some embodiments, a planarization process such as a CMP, an etch-back process, combinations thereof, or the like is utilized. After the planarization process, the top surfaces of the fourth ILD 142 and the upper source/drain contacts 96U are substantially coplanar (within process variations).

As noted above, the upper source/drain contacts 96U may include first upper source/drain contacts 96UA and second upper source/drain contacts 96UB. The first upper source/drain contacts 96UA are formed over and electrically connected to first upper epitaxial source/drain regions 62UA as well as some of the lower source/drain contacts 96L. The second upper source/drain contacts 96UB are formed over and electrically connected to second upper epitaxial source/drain regions 62UB as well as, optionally, some of the contact vias 74. Among both types, a portion of the upper source/drain contacts 96U within the fourth ILD 142 may be disposed directly over or above (e.g., and rest upon) the upper surfaces of the lower source/drain contacts 96L or the contact vias 74. In addition, another portion of the upper source/drain contacts 96U extending to the upper epitaxial source/drain regions 62U may extend along the corresponding lower source/drain contacts 96L or contact vias 74. As illustrated, the second dielectric liner 90 may be interposed there-between for a minority, a majority, or an entirety of that up-and-down boundary.

In FIGS. 14A and 14B, a fifth CESL 108 and a fifth ILD 110 may be formed over the fourth ILD 142, and gate contacts 112 and source/drain vias 114 are then formed to contact the upper gate electrodes 80U and the source/drain contacts 96, respectively. As an example to form the gate contacts 112 and the source/drain vias 114, openings for the gate contacts 112 and the source/drain vias 114 are formed through the fifth ILD 110 and the fifth CESL 108. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the fifth ILD 110. The remaining liner and conductive material form the gate contacts 112 and the source/drain vias 114 in the openings. The gate contacts 112 and the source/drain vias 114 may be formed in distinct processes, or may be formed in the same process. Although shown as being formed in the same cross-section, it should be appreciated that each of the gate contacts 112 and the source/drain vias 114 may be formed in different cross-sections, which may avoid shorting of the contacts.

A front-side interconnect structure 120 is formed on the device layer 30. The front-side interconnect structure 120 includes dielectric layers 122 and layers of conductive features 124 in the dielectric layers 122. The dielectric layers 122 may include low-k dielectric layers formed of low-k dielectric materials. The dielectric layers 122 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 122 may also include polymer layers.

The conductive features 124 may include conductive lines and vias, which may be formed using damascene processes. Conductive features 124 may include metal lines and metal vias, which includes diffusion barriers and a copper containing material over the diffusion barriers. There may also be aluminum pads over and electrically connected to the metal lines and vias. In some embodiments, contacts to the lower gate stacks 76L and the lower epitaxial source/drain regions 62L may be made through a backside of the device layer 30 (e.g., a side opposite to the front-side interconnect structure 120).

Although not specifically illustrated, contacts to the lower gate stacks 76L and the lower epitaxial source/drain regions 62L may be made through a backside of the device layer 30 (e.g., a side opposite to the front-side interconnect structure 120), in accordance with various embodiments. For example, the device layer 30 will be interposed between the front-side interconnect structure 120 and a backside interconnect structure (not specifically illustrated). The backside interconnect structure may be electrically coupled by the contacts and be substantially similar to the front-side interconnect structure 120 as described above.

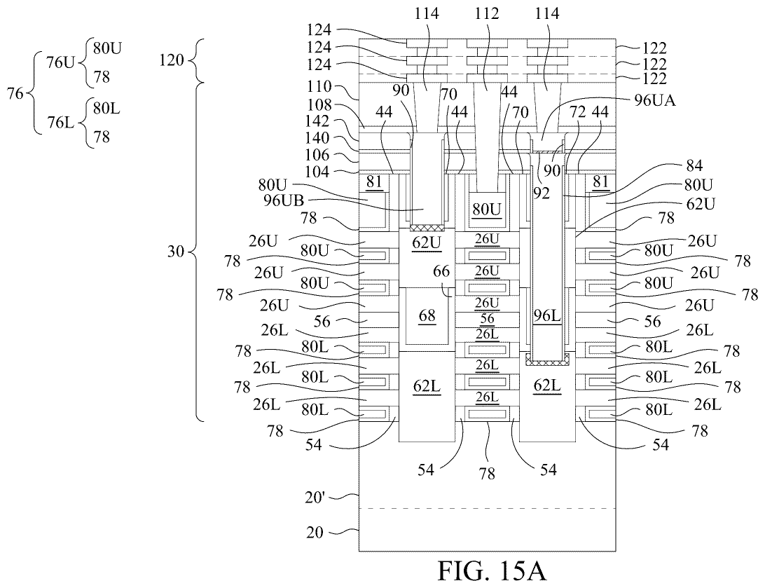

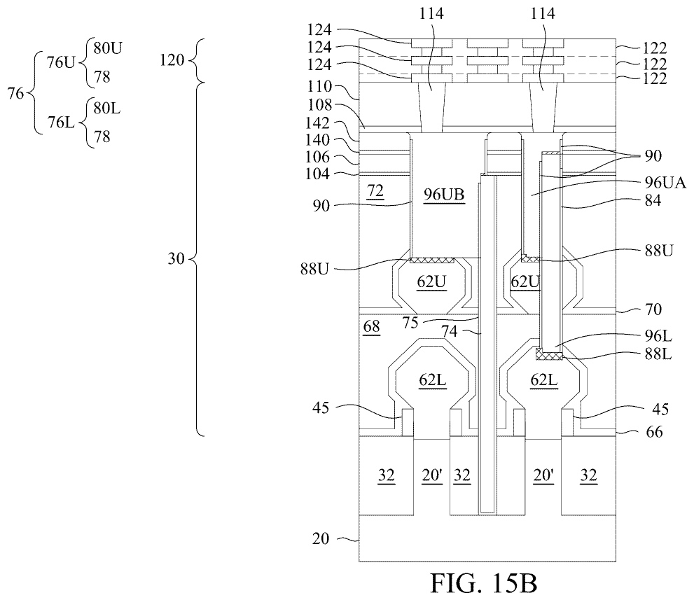

FIGS. 15A through 18 illustrate various additional embodiments and depictions related to forming the lower and upper source/drain contacts 96L, 96U (e.g., including the dual source/drain contacts 96D). Note that features discussed in connection with these embodiments may be utilized in combination with any other embodiments described above or below, where appropriate and suitable. It should be appreciated that formation of the source/drain contacts 96 (and other illustrated features) in the following embodiments may include similar processes and similar materials as described above, unless specified otherwise.

FIGS. 15A and 15B provide exemplary illustrations for how some features described above may form as consequences of reality and/or process design choices (e.g., tools or methods). For example, formation of openings, such as the source/drain contact openings 82, may be tapered such that upper portions of the openings are wider than the bulk. As a result, the source/drain contacts 96 may form with analogous shapes.

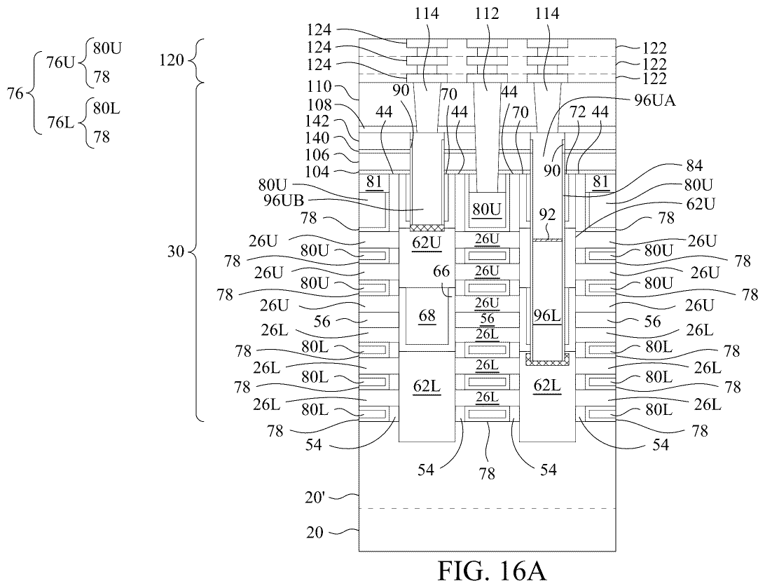

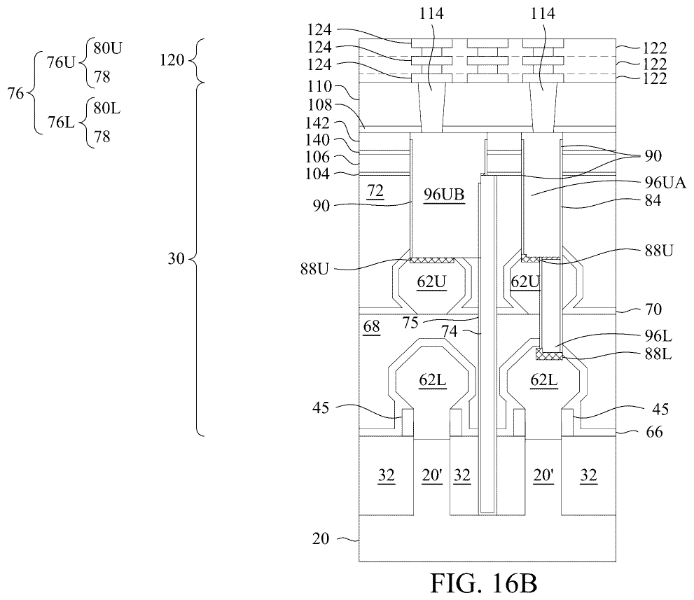

In FIGS. 16A and 16B, the lower source/drain contacts 96L may be formed to partially fill the lower source/drain contact openings 82L. For example, the lower source/drain contact 96L may be formed with an uppermost surface being lower than an uppermost surface of the upper epitaxial source/drain region 62U which the lower source/drain contact opening 84L and the lower source/drain contact 96L extend through. The first upper source/drain contact opening 82UA includes a portion within the third ILD 106 and the fourth ILD 142 that is disposed directly over or above (e.g., and rest upon) the upper surface of the lower source/drain contact 96L. In addition, there may be little to no up-and-down boundary between the first upper source/drain contact 96UA and the corresponding lower source/drain contact 96L.

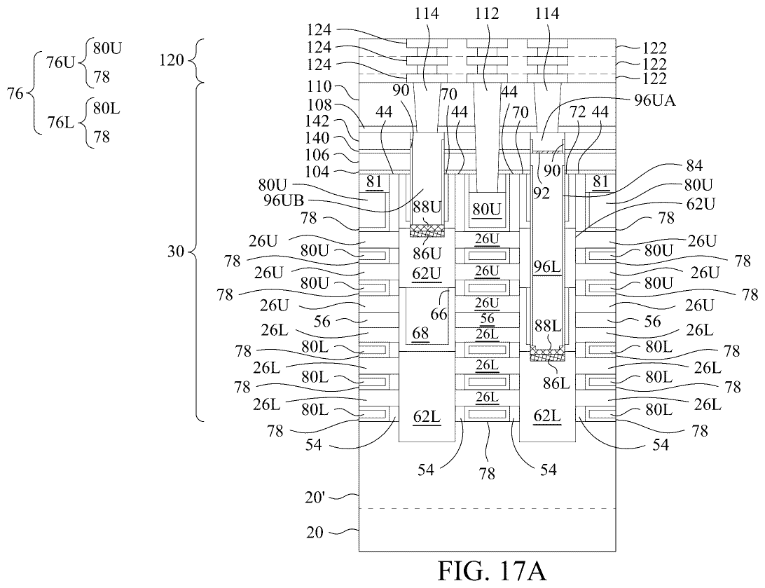

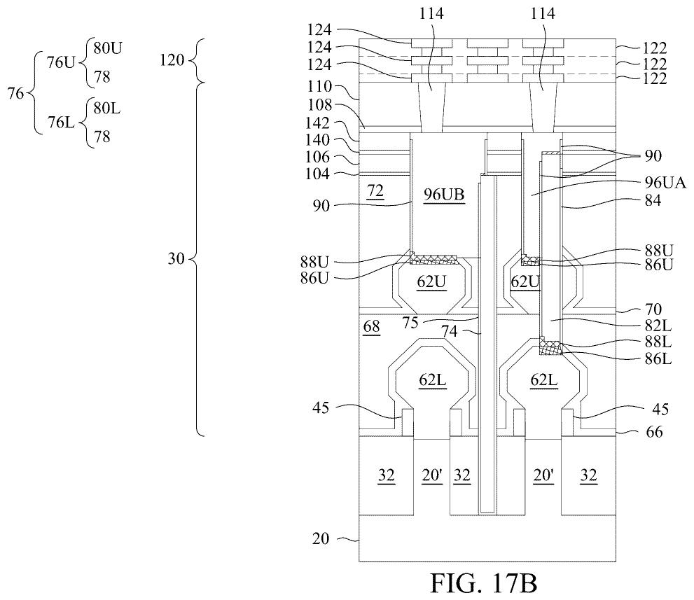

In FIGS. 17A and 17B, before forming the lower metal-semiconductor alloy 88L (see FIGS. 8A and 8B), a first epitaxial regrowth process may be performed to form lower epitaxial regrowth layers 86L on the lower epitaxial source/drain regions 62L. This process is particularly useful when the lower epitaxial source/drain regions 62L are over-etched during formation of the lower source/drain contact openings 82L. In accordance with some embodiments, the first epitaxial regrowth process may comprise a low temperature epitaxial growth process. In embodiments in which the lower epitaxial source/drain regions 62L correspond to p-type lower transistors, the lower epitaxial regrowth layers 86L may include SiB, SiGe, SiGeB, or combinations thereof and be deposited at temperatures of between 350° C. and 400° C. In embodiments in which the lower epitaxial source/drain regions 62L correspond to n-type lower transistors, the lower epitaxial regrowth layers 86L may include SiP, SiAs, or a combination thereof and be deposited at temperatures of between 350° C. and 400° C. Deposition temperatures of less than 400° C. serve to reduce the thermal budget while protecting other parts of the stacking transistor structure.

As further illustrated, before forming the upper metal-semiconductor alloy regions 88U (see FIGS. 12A and 12B), a second epitaxial regrowth process may be performed to form upper epitaxial regrowth layers 86U on the upper epitaxial source/drain regions 62U. This process is particularly useful when the upper epitaxial source/drain regions 62U are over-etched during formation of the upper source/drain contact openings 82U. In accordance with some embodiments, the second epitaxial regrowth process may comprise a low temperature epitaxial growth process. In embodiments in which the upper epitaxial source/drain regions 62U correspond to n-type lower transistors, the upper epitaxial regrowth layers 86U may include SiP, SiAs, or a combination thereof and be deposited at temperatures of between 350° C. and 400° C. In embodiments in which the upper epitaxial source/drain regions 62U correspond to p-type upper transistors, the upper epitaxial regrowth layers 86U may include SiB, SiGe, SiGeB, or combinations thereof and be deposited at temperatures of between 350° C. and 400° C. Deposition temperatures of less than 400° C. serve to reduce the thermal budget while protecting other parts of the stacking transistor structure.

In some embodiments (not specifically illustrated), the first epitaxial regrowth process is performed on the lower epitaxial source/drain regions 62L, whereas the second epitaxial regrowth process may not be performed on the upper epitaxial source/drain regions 62U. In other embodiments (not specifically illustrated), the second epitaxial regrowth process is performed on the upper epitaxial source/drain regions 62U, whereas the first epitaxial regrowth process may not be performed on the lower epitaxial source/drain regions 62L.

In FIG. 18, the metal nitride layer 92 (e.g., titanium nitride) may form and remain on exposed sidewall surfaces of one or both of the lower source/drain contacts 96L and the contact vias 74. In such embodiments, above-described treatments that impact the metal nitride layer 92 (e.g., the implantation process) may reduce an interface resistance in regard to the upper surface portion of the metal nitride layer 92, while the sidewall portion of the metal nitride layer 92 remains substantially intact. As a result, the upper surface portion of the metal nitride layer 92 may have the lower interface resistance with adjacent conductive features, while the sidewall surface portion of the metal nitride layer 92 may have the higher interface resistance with adjacent conductive features.

In some embodiments (not specifically illustrated), the metal nitride layer 92 may form on the exposed surfaces (e.g., the top surfaces and/or the sidewall surfaces) of the lower source/drain contacts 96L while the contact vias 74 remain substantially free of the metal nitride layer 92. This may occur depending on the metals used to form the upper metal-semiconductor alloy regions 88U as well as differences between the first conductive material of the lower source/drain contacts 96L and the conductive material of the contact vias 74.

Various advantages are achieved during formation of the source/drain contacts 96 of stacking transistors. In particular, implantation processes and epitaxial regrowth processes can be selected with greater specificity based on the differing materials of the upper and lower epitaxial source/drain regions 62U, 62L. In addition, depositing the first conductive material into the lower source/drain contact openings 82L may proceed more efficiently and with a reduction in voids, such that the resulting lower source/drain contacts 96L are substantially seamless. As a result, the epitaxial source/drain regions 62 and the source/drain contacts 96 are formed with greater tuning and improved yield, which results in higher performance and reliability of the stacking transistors.

In an embodiment, a method includes patterning a first opening through a first dielectric layer, a first source/drain region, and a second dielectric layer to expose and second source/drain region; forming a first dielectric liner along sidewalls of the first opening, wherein the second source/drain region is exposed; forming a first metal-semiconductor alloy region in the first opening along the second source/drain region; depositing a first conductive material to fill a remainder of the first opening; patterning a second opening through the first dielectric layer to expose the first source/drain region; forming a second dielectric liner along sidewalls of the second opening, wherein the first source/drain region is exposed; forming a second metal-semiconductor alloy region in the second opening along the first source/drain region; and depositing a second conductive material to fill a remainder of the second opening. In another embodiment, patterning the second opening includes exposing a sidewall of the first conductive material. In another embodiment, the second dielectric liner is formed along a portion of the exposed sidewall of the first conductive material. In another embodiment, the method further includes, before forming the first metal-semiconductor alloy region, forming a first semiconductor material to regrow the second source/drain region, wherein the first metal-semiconductor alloy region is formed along the first semiconductor material of the second source/drain region. In another embodiment, the method further includes, before forming the second metal-semiconductor alloy region, forming a second semiconductor material to regrow the first source/drain region, wherein the second metal-semiconductor alloy region is formed along the second semiconductor material of the first source/drain region. In another embodiment, the first semiconductor material includes a silicon germanium epitaxial layer, and wherein the second semiconductor material includes a silicon epitaxial layer. In another embodiment, forming the first metal-semiconductor alloy region includes forming a metal nitride layer over the first conductive material. In another embodiment, after depositing the second conductive material, the metal nitride layer is interposed between the first conductive material and the second conductive material.

In an embodiment, a method includes etching a first opening through a plurality of layers to expose a first epitaxial region disposed over a semiconductor substrate, the first epitaxial region includes a first semiconductor material, the plurality of layers includes a first dielectric layer disposed over the first epitaxial region; a second epitaxial region disposed over the first dielectric layer, the second epitaxial region includes a second semiconductor material; and a second dielectric layer disposed over the second epitaxial region; forming a first dielectric liner along surfaces of the first opening; etching to remove a bottom segment of the first dielectric liner; depositing a silicon germanium material over the first epitaxial region; filling the first opening with a first conductive material disposed over the silicon germanium material; etching a second opening through the second dielectric layer to expose the second epitaxial region; forming a second dielectric liner along surfaces of the second opening; etching to remove a bottom segment of the second dielectric liner; and filling the second opening with a second conductive material disposed over the second epitaxial region, the first conductive material being electrically connected to the second conductive material. In another embodiment, the method further includes, before filling the first opening: depositing one or more first metals over the first epitaxial region; and performing a first anneal to convert at least a portion of the one or more first metals into a first metal-semiconductor alloy. In another embodiment, the method further includes, before filling the second opening: depositing one or more second metals over the first epitaxial region; and performing a second anneal to convert at least a portion of the one or more second metals into a second metal-semiconductor alloy. In another embodiment, the one or more second metals includes titanium, wherein after performing the second anneal, a titanium-containing layer is disposed along a surface of the first conductive material, and wherein an interface between the titanium-containing layer and the first conductive material has a first resistance at a set of standard conditions. In another embodiment, the method further includes, before filling the second opening, performing an implantation process of dopants through the second metal-semiconductor alloy, wherein after performing the implantation process, the interface between the titanium-containing layer and the first conductive material has a second resistance at the set of standard conditions, and wherein the second resistance is less than the first resistance. In another embodiment, the first semiconductor material includes silicon germanium, wherein the second semiconductor material includes silicon, and wherein the titanium-containing layer includes titanium nitride.

In an embodiment, a semiconductor device includes: a first dielectric layer disposed over a substrate and below a second dielectric layer; a first source/drain region within the first dielectric layer, the first source/drain region includes a first semiconductor layer with a first element and a second semiconductor layer with the first element, wherein a concentration of the first element of the first semiconductor layer changes in a direction towards the substrate, and wherein a thickness of the first source/drain region is different from a width of the first source/drain region in a cross-sectional view; a second source/drain region within the second dielectric layer; a first source/drain contact being electrically coupled to a first upper surface of the first source/drain region and extending through the first dielectric layer and the second source/drain region, the first source/drain contact being separated from the second source/drain region by a first dielectric liner; a second source/drain contact being electrically coupled to a second upper surface of the second source/drain region and extending through the second dielectric layer; first nanostructures adjacent to the first source/drain region; second nanostructures adjacent to the second source/drain region; a first gate structure around the first nanostructures; and a second gate structure over the first gate structure and around the second nanostructures. In another embodiment, the first source/drain contact is electrically coupled to the second source/drain contact. In another embodiment, a third upper surface of the first source/drain contact is level with an interior region of the second source/drain region. In another embodiment, the first source/drain contact extends through an entire thickness of the second dielectric layer. In another embodiment, the semiconductor device further includes: a contact via extending from the substrate through the first dielectric layer and the second dielectric layer; a third source/drain region within the second dielectric layer; and a third source/drain contact being electrically coupled to a fourth upper surface of the third source/drain region and extending through the second dielectric layer. In another embodiment, the third source/drain contact is electrically coupled to the contact via.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method comprising:
patterning a first opening through a first dielectric layer, a first source/drain region, and a second dielectric layer to expose a second source/drain region;
forming a first dielectric liner along sidewalls of the first opening, wherein the second source/drain region is exposed;
forming a first metal-semiconductor alloy region in the first opening along the second source/drain region;
depositing a first conductive material to fill a remainder of the first opening;
patterning a second opening through the first dielectric layer to expose the first source/drain region;
forming a second dielectric liner along sidewalls of the second opening, wherein the first source/drain region is exposed;
forming a second metal-semiconductor alloy region in the second opening along the first source/drain region; and
depositing a second conductive material to fill a remainder of the second opening.

2. The method of claim 1, wherein patterning the second opening comprises exposing a sidewall of the first conductive material.

3. The method of claim 2, wherein the second dielectric liner is formed along a portion of the exposed sidewall of the first conductive material.

4. The method of claim 1, further comprising, before forming the first metal-semiconductor alloy region, forming a first semiconductor material to regrow the second source/drain region, wherein the first metal-semiconductor alloy region is formed along the first semiconductor material of the second source/drain region.

5. The method of claim 4, further comprising, before forming the second metal-semiconductor alloy region, forming a second semiconductor material to regrow the first source/drain region, wherein the second metal-semiconductor alloy region is formed along the second semiconductor material of the first source/drain region.

6. The method of claim 5, wherein the first semiconductor material comprises a silicon germanium epitaxial layer, and wherein the second semiconductor material comprises a silicon epitaxial layer.

7. The method of claim 1, wherein forming the first metal-semiconductor alloy region comprises forming a metal nitride layer over the first conductive material.

8. The method of claim 7, wherein after depositing the second conductive material, the metal nitride layer is interposed between the first conductive material and the second conductive material.

9. A method comprising:
etching a first opening through a plurality of layers to expose a first epitaxial region disposed over a semiconductor substrate, the first epitaxial region comprising a first semiconductor material, the plurality of layers comprising:
a first dielectric layer disposed over the first epitaxial region;
a second epitaxial region disposed over the first dielectric layer, the second epitaxial region comprising a second semiconductor material; and
a second dielectric layer disposed over the second epitaxial region;
forming a first dielectric liner along surfaces of the first opening;
etching to remove a bottom segment of the first dielectric liner;
depositing a silicon germanium material over the first epitaxial region;
filling the first opening with a first conductive material disposed over the silicon germanium material;
etching a second opening through the second dielectric layer to expose the second epitaxial region;
forming a second dielectric liner along surfaces of the second opening;
etching to remove a bottom segment of the second dielectric liner; and
filling the second opening with a second conductive material disposed over the second epitaxial region, the first conductive material being electrically connected to the second conductive material.

10. The method of claim 9, further comprising, before filling the first opening:
depositing one or more first metals over the first epitaxial region; and
performing a first anneal to convert at least a portion of the one or more first metals into a first metal-semiconductor alloy.

11. The method of claim 10, further comprising, before filling the second opening:
depositing one or more second metals over the first epitaxial region; and
performing a second anneal to convert at least a portion of the one or more second metals into a second metal-semiconductor alloy.

12. The method of claim 11, wherein the one or more second metals comprises titanium, wherein after performing the second anneal, a titanium-containing layer is disposed along a surface of the first conductive material, and wherein an interface between the titanium-containing layer and the first conductive material has a first resistance at a set of standard conditions.

13. The method of claim 12, further comprising, before filling the second opening, performing an implantation process of dopants through the second metal-semiconductor alloy, wherein after performing the implantation process, the interface between the titanium-containing layer and the first conductive material has a second resistance at the set of standard conditions, and wherein the second resistance is less than the first resistance.

14. The method of claim 12, wherein the first semiconductor material comprises silicon germanium, wherein the second semiconductor material comprises silicon, and wherein the titanium-containing layer comprises titanium nitride.

15. A semiconductor device comprising:
a first dielectric layer disposed over a substrate and below a second dielectric layer;
a first source/drain region within the first dielectric layer, the first source/drain region comprising a first semiconductor layer with a first element and a second semiconductor layer with the first element, wherein a concentration of the first element of the first semiconductor layer changes in a direction towards the substrate, and wherein a thickness of the first source/drain region is different from a width of the first source/drain region in a cross-sectional view;
a second source/drain region within the second dielectric layer;
a first source/drain contact being electrically coupled to a first upper surface of the first source/drain region and extending through the first dielectric layer and the second source/drain region, the first source/drain contact being separated from the second source/drain region by a first dielectric liner;
a second source/drain contact being electrically coupled to a second upper surface of the second source/drain region and extending through the second dielectric layer;
first nanostructures adjacent to the first source/drain region;
second nanostructures adjacent to the second source/drain region;
a first gate structure around the first nanostructures; and
a second gate structure over the first gate structure and around the second nanostructures.

16. The semiconductor device of claim 15, wherein the first source/drain contact is electrically coupled to the second source/drain contact.

17. The semiconductor device of claim 16, wherein a third upper surface of the first source/drain contact is level with an interior region of the second source/drain region.

18. The semiconductor device of claim 16, wherein the first source/drain contact extends through an entire thickness of the second dielectric layer.

19. The semiconductor device of claim 15, further comprising:
a contact via extending from the substrate through the first dielectric layer and the second dielectric layer;
a third source/drain region within the second dielectric layer; and
a third source/drain contact being electrically coupled to a fourth upper surface of the third source/drain region and extending through the second dielectric layer.

20. The semiconductor device of claim 19, wherein the third source/drain contact is electrically coupled to the contact via.
